(19) United States
(12) Patent Application Publication
(10) Pub. No.: US 2007/0066076 A1
(43) Pub. Date: Mar. 22, 2007

(54) Substrate processing method and apparatus using a combustion flame

(76) Inventors: Joel B. Bailey, Austin, TX (US); Johnny D. Ortiz, Round Rock, TX (US); Michael D. Robbins, Round Rock, TX (US); Richard E. Rock, Round Rock, TX (US)

Correspondence Address: HARNESS, DICKEY & PIERCE, P.L.C., P.O. BOX 828, BLOOMFIELD HILLS, MI, 48303, US

(21) Appl. No.: 11/230,261

(22) Filed: Sep. 19, 2005

(51) Int. Cl. H01L 21/302; H01L 21/461

(52) U.S. Cl. 438/710; 438/746

(57) ABSTRACT

A substrate processing method and apparatus using a combustion flame of a gaseous mixture of hydrogen and a non-oxygen oxidizer is described. The method uses the hydrogen and non-oxygen oxidizer combustion flame to impinge upon a substrate surface for chemically reacting with a thin film on the surface and thus etching the substrate. The method is performed in a substantially inert and non-ionized environment at a substantially atmospheric pressure. An apparatus for processing a substrate with the method has a processing chamber for containing the inert environment and a nozzle head for directing the combustion flame towards a substrate retained upon a substrate holder. In an embodiment, an edge nozzle assembly is angled towards the edge of the wafer for treating the near-edge and edge of the wafer. In this embodiment, a heater preheats the substrate in the near-edge region to be processed.

### FIELD OF THE INVENTION

The present invention relates to a method and apparatus for processing a substrate using a combustion flame and more particularly, a method and apparatus for etching a surface of the substrate with a combustion flame of hydrogen and a non-oxygen oxidizer in a non-ionized environment.

### BACKGROUND

During the manufacture of integrated circuits, silicon substrate wafers receive extensive processing including deposition and etching of dielectrics, metals, and other materials. At varying stages in the manufacturing process it is necessary to “clean” the in-process wafer to remove unwanted thin films and contaminants. This includes thin films and contaminants that develop on a top side (primary processed side), back side, and edge area (near-edge, bevels, and crown) of the wafer. It is a challenge to remove thin films and contaminants in an efficient and cost effective manner. This challenge is exacerbated by use of chemistries and processes that may adversely impact the final product.

Various known options exist for effecting removal of thin films and contaminants. Etching can occur in a wet or dry processing environment. Wet chemical etching refers to the contact of the wafer surface with a liquid chemical etchant. Material is removed as an agitated liquid or spray, for example, passes over the substrate surface. Dry etching generally refers to the contact of the substrate surface with a gaseous plasma etchant.

Wet chemical etching is used extensively in wafer processing. Even prior to thermal oxidation or epitaxial growth, wafers are chemically cleaned to remove contamination that results from handling and storing. In wet chemical etching the chemical reactants in a liquid or vapor state are transported by diffusion to the reacting surface, chemical reactions occur at the surface, and the products from the surface are removed. One form of wet chemical etching commonly used for silicon etching is formed of a mixture of nitric acid (HNO₃) and hydrofluoric acid (liquid HF). Nitric acid oxidizes the silicon to form a SiO₂ layer and hydrofluoric acid is used to dissolve the SiO₂ layer. However, chemical etching has its limitations and is not desirable in all applications. One problem associated with wet chemical etching is that etched material constituents may move within etched or partially etched openings on the wafer surface. Further, wet etching may result in incomplete or non-uniform etching. In addition, wet etching is isotropic resulting in an imprecise etching. In addition wet etching requires repeated drying of the wafer between processing steps thus adding time and cost to the process.

Dry etching usually meaning plasma assisted etching denotes several techniques that use plasma in the form of low pressure discharges. Dry etch plasma methods include plasma etching, reactive ion etching (RIE), sputter etching, reactive ion beam etching and other plasma based etching methods.

A plasma is produced when an electric field (or electromagnetic field) of sufficient magnitude is applied to the gas, causing the gas to break down and become ionized. As a result, plasma is a fully or partially ionized gas. Many chemistries have been used in plasma processing of wafers including plasmas using hydrogen (H₂), and nitrogen trifluoride (NF₃). However, dry, plasma based etching has its own limitations and problems. This includes difficulty in processing only a part of the wafer, for example, the wafer edge. Diffusion effects dominate at low operating pressures making it difficult to control exposure location on the wafer. For entire wafer processing, ion and charge induced damage can occur. Further, equipment overhead for these processes is cumbersome, requiring vacuum chambers and pumping equipment. Vacuum requirements can also reduce throughput and increase equipment and operating costs.

Near atmospheric pressure plasma sources, such as disclosed in U.S. Pat. No. 5,961,772, can also be used for wafer processing. These types of reactive species sources are more amenable to partial wafer processing where part of the substrate is moved proximate to the output gas flow of the source. The difficulty of this type of process is the large helium flow required to maintain a stable discharge. High consumption of helium (a non-renewable resource) drives up operating costs. In addition, lower material removal rates are generally realized with this type of process due to lower gas effluent temperatures supplying proportionately lower activation energy to the substrate. These factors combine to increase process cost per wafer.

Combustion flames formed of hydrogen (H₂) and oxygen (O₂) have also been used to process a substrate surface, for example as disclosed in U.S. Pat. No. 5,314,847. The inclusion of oxygen as the oxidizer inherently limits the resulting reactive species to etching of only certain thin films.

Apart from wet chemical and dry plasma-based processing, abrasive polishing methods have been used to treat bevel and crown areas of the wafer edge. These methods, however, are inherently dirty and tend to cause particulate contamination and subsequent defects in the substrate. This necessitates a post-treatment step of additional cleaning. Another issue with abrasive methods is sub-surface damage left after the process. This damage is induced in the substrate Si crystalline structure as a result of the process and can have negative effects during subsequent processing.

Therefore, each of the above described processes has inherent limitations and problems that restrict its suitability for certain applications particularly where the requirement is for cleaning a thin film or contaminant from the wafer including the wafer top side, edge area and back side. There is a need for a method for processing substrates that avoids the inherent problems with wet chemical, dry plasma, and abrasive methods of processing a wafer. It is important that the method be efficient, cost effective and not result in damage or the necessity of performing further process steps on the wafer.

### SUMMARY OF THE INVENTION

In accordance with the present invention, a substrate processing method and apparatus provides advantages over the aforementioned processing methods and systems. In one aspect the present invention is directed to a method and apparatus for processing a substrate using a combustion flame of a mixture of hydrogen gas and a non-oxygen oxidizer gas such as nitrogen trifluoride in a non-ionized environment. In another aspect of the present invention processing may be performed in an inert environment and preheating may be used to preheat the substrate. In a further aspect of the invention the heater used to preheat the substrate is a fiber coupled laser diode array. In yet a further aspect of the invention also includes a wafer substrate processed as a result of this apparatus or method.

Yet another aspect of the invention includes a method for processing the substrate comprising igniting the combustion flame of hydrogen and the non-oxygen oxidizer, and directing the combustion onto the surface of the substrate.

An apparatus for processing the substrate with a combustion flame of hydrogen and a non-oxygen oxidizer comprises a processing chamber for receiving the substrate and for confining an inert environment for the combustion flame of hydrogen and the non-oxygen oxidizer wherein the processing chamber maintains a substantially atmospheric pressure and is non-ionized, in still a further aspect of the present invention. In an additional aspect of the present invention the apparatus also has a nozzle assembly within the processing chamber for directing the combustion flame onto the substrate. In an additional aspect of the present invention the nozzle assembly comprises nozzles formed of sapphire, or yttria (Y₂O₃), or magnesium fluoride (MgF₂) or magnesium oxide (MgO).

Thus, the invention advantageously provides for a cost effective, efficient method and apparatus for processing the surface of a substrate by directing a combustion flame of hydrogen and the non-oxygen oxidizer onto the substrate surface. A chemical reaction is allowed to proceed where a thin film or contaminant undergoes a change from a solid to a gas byproduct and is easily evacuated. Further, the exothermic combustion reaction of hydrogen and nitrogen trifluoride provides a high etch rate resulting in high throughput of processed substrates. In addition, the combustion flame may be directed to discreet areas of the substrate including the substrate edge area thus allowing for precise processing of the substrate.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

The present invention will become more fully understood from the detailed description and the accompanying drawings, wherein:

FIGS. 1A-1C shows schematic representations of a substrate surface processing method of a preferred embodiment of the present invention;

FIG. 2 shows a schematic representation of the preferred embodiment of the invention as an apparatus for processing a substrate using the method as shown in FIGS. 1A-1C;

FIG. 3 shows a detailed schematic view of a nozzle assembly of the preferred embodiment of the apparatus as shown in FIG. 2;

FIG. 4 shows a schematic representation of an preferred embodiment of the invention as an apparatus for processing a substrate wafer edge using the method as shown in FIGS. 1A-1C; and

FIG. 5 shows a detailed schematic view of an edge-type nozzle assembly of the preferred embodiment of the apparatus as shown in FIG. 4.

### DETAILED DESCRIPTION OF THE PREFERRED EMBODIMENTS

The following description of the preferred embodiments is merely exemplary in nature and is in no way intended to limit the invention, its application, or uses.

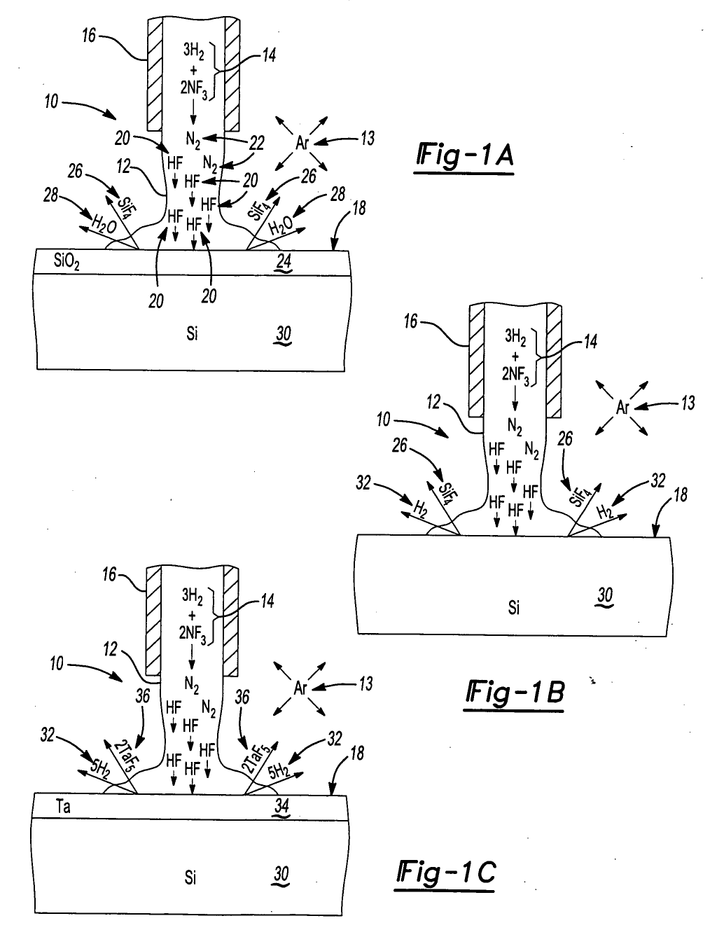

Referring to FIGS. 1A-1C a preferred embodiment of a substrate processing method 10 of the invention employs a combustion flame 12 formed of an ignited combustion of gaseous reactants 14 including hydrogen (H₂) and nitrogen trifluoride (NF₃, as a non-oxygen “oxidizer”) in an inert ambient environment 13 of argon gas. Although argon is illustrated other inert gases are suitable. A mixture of gaseous reactants 14 passes through a torch nozzle 16 before igniting into combustion flame 12. Although one torch nozzle 16 is illustrated more than one nozzle may be used. Combustion flame 12 impinges upon a substrate surface 18.

Gaseous reactants 14 react in combustion flame 12 to form gaseous hydrogen fluoride (HF) 20 (a reactive species) and gaseous nitrogen (N₂) 22 effluents. The following chemical equation describes the production of gaseous hydrogen fluoride 20 and gaseous nitrogen 22 from gaseous reactants 14 based on a stoichiometric mixture (a 3:2 molar ratio):
3H₂ (gas)+2NF₃ (gas)→6HF (gas)+N₂ (gas)
Advantageously, this reaction is performed substantially at atmospheric pressure. This allows for use of viscous (rather than molecular) flow properties to precisely treat portions of the substrate surface 18 and minimize exposure of other substrate areas to the reactive process. Although a 3:2 molar ratio is described higher or lower ratios may be used depending on the desired result.

Further, this reaction is not induced by an ion producing field consistent with a plasma. It is believed that a plasma is a collection of charged particles where the long-range electromagnetic fields set up collectively by the charged particles have an important effect on the particles' behavior. It is also believed that the combustion flame 12 has substantially no ionic species present. As a result, there is no risk of ionic damage to the substrate.

Further, substantial heat is generated from the exothermic chemical reaction of H₂ and NF₃. This effect allows a small volume of highly reactive species in the form of HF to be generated due to the amount of energy represented by the resultant temperature. Elevated temperature in turn substantially increases reaction rates which results in higher etch rates. The result is higher process throughput.

A silicon dioxide thin film 24 (FIG. 1a) is etched by the gaseous hydrogen fluoride 20 according to the following overall reaction:
4HF (gas)+SiO₂ (solid)→SiF₄ (gas)+2H₂O (vapor)
Gaseous silicon tetrafluoride 26 and water vapor 28 leave the surface of the silicon dioxide thin film 24 (FIG. 1a). Advantageously, this reaction provides for a change of silicon dioxide thin film 24 (FIG. 1a) from a solid to a gas byproduct that can be easily evacuated.

Gaseous hydrogen fluoride 20 will also etch a substrate surface 18 of silicon 30 (FIG. 1b). Silicon 30 etching follows the following overall reaction:
4HF (gas)+Si (solid)→SiF₄ (gas)+2H₂ (gas)
In this reaction, gaseous silicon tetrafluoride 26 and gaseous hydrogen 32 leave the silicon 30 substrate surface 18 (FIG. 1b). This reaction provides for a change of silicon 30 on the substrate surface 18 (FIG. 1b) from a solid to a gas byproduct that can be evacuated.

Similarly, etching of a tantalum thin film 34 (FIG. 1c) follows the following overall reaction:
10HF (gas)+2Ta (solid)→2TaF₅ (gas)+5H₂ (gas)
In this reaction, gaseous tantalum pentafluoride 36 and gaseous hydrogen 32 leave the tantalum 34 substrate surface 18 (FIG. 1c). This reaction provides for a change of the tantalum 34 on the substrate surface 18 (FIG. 1c) from a solid to a gas byproduct that can be evacuated.

Organic and polymer films can also be removed using the above described chemistry however selectivity issues to Si and SiO₂ may in some instances make this less desirable. The above chemistry for example can be used to etch SiO₂ over Si where etching of oxide is desirable but Si is not. Passivation of exposed Si to the etch chemistry can be promoted by first exposing an etch field to a hydrogen rich flame with oxygen. The etch field is then exposed to the combustion flame of H₂ and NF₃ where the oxide is etched.

Other desirable non-oxygen oxidizers for reaction with hydrogen in a combustion flame for substrate etching include fluoride (F₂), chlorine (Cl₂), and chlorine trifluoride (ClF₃). Hydrogen and fluoride react in a combustion flame as follows:
H₂ (gas)+F₂ (gas)→2HF (gas)
Similarly to the combustion flame of H₂ and NF₃ the resulting HF reactive species is a desirable etchant as described above.

Hydrogen and chlorine react in a combustion flame as follows:
H₂ (gas)+Cl₂ (gas)→2HCl (gas)
Hydrogen and chlorine trifluoride react in a combustion flame as follows:
4H₂ (gas)+2ClF₃ (gas)→6HF (gas)+2HCl (gas)
In both the proceeding combustion flame reactions the resultant hydrogen chloride reactive species can be advantageously used for etching when materials not readily etched by fluorine are present in the film stack. This includes a film stack comprising aluminum. Hydrogen chloride as a reactive species etches aluminum as follows:
2Al (solid)+6HCl (gas)→2AlCl₃ (gas)+3H₂ (gas)
Hydrogen chloride etches silicon as follows:
Si (solid)+4HCl (gas)→SiCl₄ (gas)+2H₂ (gas)
Hydrogen chloride etches silicon oxide as follows:
SiO₂ (solid)+4HCl (gas)→SiCl₄ (gas)+2 H₂O (vapor)

Chlorine trifluoride represents a hybrid etch chemistry where both fluorine and chlorine based etchant reactive species are produced. Often this compound is combined with another fluorine containing gas (such as NF₃ or CF₄) or with Cl₂ is used in varying ratios when multiple materials are present in the film stack, requiring both fluorine and chlorine based chemistry for removal.

The chemical equations shown above are a simplified view of the real reactions taking place within the combustion flame 12 and on the substrate surface 18. The reaction chemistries occurring are quite complex resulting in intermediate and final reaction products.

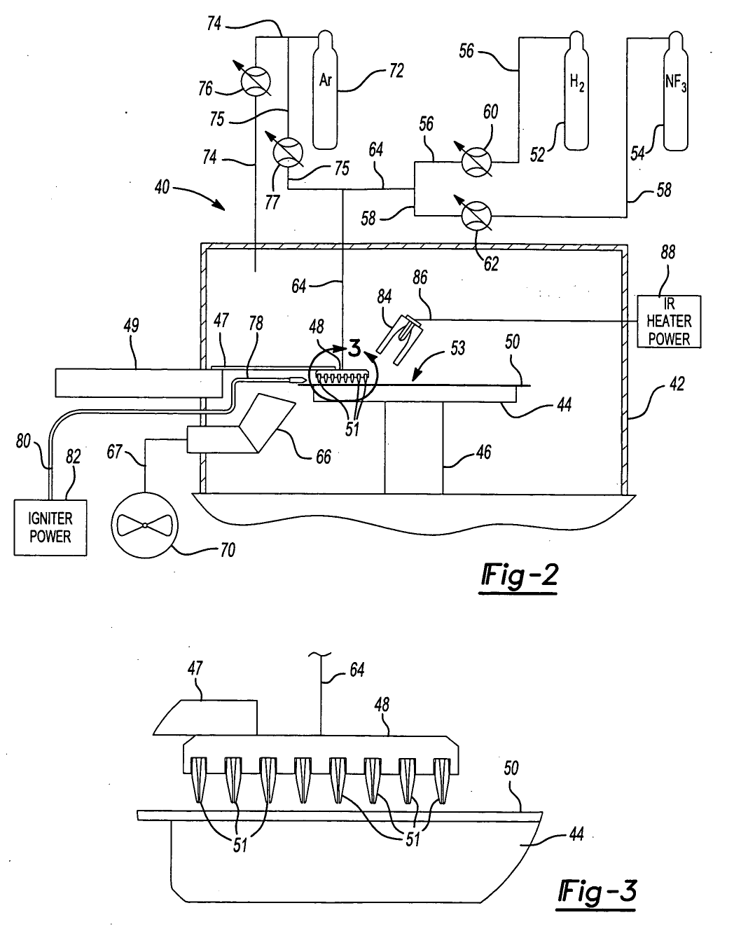

Now referring to FIGS. 2 and 3 a substrate processing apparatus 40 for processing a substrate surface with the above-described processing method will be described. A processing chamber 42 surrounds a substrate holder 44 connected to a substrate chuck 46.

A nozzle assembly 48 is held by a support member 47 over a wafer 50 retained on the substrate holder 44. Eight nozzles 51 are disposed in the nozzle assembly 48. The support member 47 is connected to an actuation mechanism 49 for directing movement of the nozzle assembly 48 over and above a wafer top surface 53. The nozzle assembly 48 is maintained at a distance of ˜1.5 mm from the wafer top surface 53 during processing.

A hydrogen gas source 52 and nitrogen trifluoride gas source 54 are connected by a first gas line 56 and second gas line 58 through a first gas controller 60 and second gas controller 62 to a common mixing gas line 64 connected to the nozzle assembly 48 for combining and mixing H₂ and NF₃. An exhaust scoop 66 is adjacent to the substrate holder 44 for exhausting gases and reactant byproducts. The exhaust scoop is connected by a plenum 67 to a blower device 70. The exhaust scoop 66 draws gases and reactant byproducts out of the processing chamber 42 through the blower device 70.

An argon gas source 72 is connected by a third gas line 74 through a third gas controller 76 to the processing chamber 42. The argon gas source 72 is also connected by a fourth gas line 75 through a fourth gas controller 77 to the common mixing gas line 64. An igniter 78 positioned close to the nozzle assembly 48 is connected by wires 80 to an igniter power supply 82.

A heater 84 is positioned proximately to the area of the wafer 50 to be processed. The heater 84 is shown as an infrared (IR) heater and is connected by an IR heater wire 86 to an IR heater power source 88. In a preferred embodiment the heater 84 is a fiber optic coupled laser diode array. A fiber optic cable assembly can be used in place of the heater 84. The fiber optic cable can deliver high power illumination originating in a laser diode assembly located remotely. Such illumination can perform heating of the wafer 50 such as discussed in United States Patent Application Publication No. 20050189329, titled “Laser Thermal Processing with Laser Diode Radiation” and incorporated herein by reference.

The eight nozzles 51 are disposed lineally in the nozzle assembly 48 and separated by a distance of 4.98 mm between a center of bore of each nozzle. Preferably the nozzle assembly 48 is constructed of 316L stainless steel and is electro-polished after fabrication. Aluminum components of the system exposed to reactive chemistries are thermal sprayed with alumina ceramic coatings to provide superior chemical and thermal resistance.

Each of the eight nozzles 51 is constructed of sapphire with a bore diameter of 0.254 mm and an aspect ratio of 10:1 at the outlet end. Each of the eight nozzles 51 is press fitted into the nozzle assembly 48. The nozzles are pressed into tightly toleranced bores cut into the stainless steel nozzle assembly 48. Nozzle diameter is 1.577 mm, +0.003 mm, −0.000 mm. Bore diameter in the nozzle assembly 48 for receiving the sapphire nozzle is 1.567 mm, +0.003 mm, −0.000 mm. This gives an interference fit in the range of 0.007 mm to 0.013 mm. Tolerance of this fit is important as interference in this range allows a hermetic seal while only inducing elastic deformation in the stainless steel nozzle assembly 48. This allows a good seal without causing particulate generation during processing.

In an embodiment, substrate holder 44 is rotated by the substrate chuck 46 while actuation mechanism 49 moves nozzle assembly 48 linearly from at or near the edge of the wafer 50 to the center of the wafer 50. Thus, the entire wafer top surface 53 can be processed. Movement of the actuation mechanism 49 and substrate chuck 46 is computer controlled (not shown).

In an alternative embodiment, substrate holder 44 is rotated, and translated in one or more directions by the substrate chuck 46 while the nozzle assembly 48 is maintained stationary. Thus, in either embodiment the entire wafer top surface 53 can be processed. Either embodiment is intended to ensure uniform exposure of the wafer 50 to the process chemistry.

In operation, the wafer 50 is first centered on the substrate holder 44 of the substrate chuck 46 in preparation for processing the wafer top surface 53. The substrate chuck 46 is commanded to rotate the substrate holder 44 with the wafer 50. Next, the exhaust scoop 66 is activated by energizing the blower device 70. Third gas controller 76 is opened to allow for a flow of argon gas from the argon gas source 72 into the processing chamber 42. Argon gas is allowed to flow into the chamber to substantially create an inert environment within the processing chamber 42. In an embodiment the argon gas may be directed to the process area and the processing chamber 42 may contain other ambient gasses. The processing chamber 42 remains substantially at atmospheric pressure.

Heater 84 is energized to heat the wafer top surface 53. This step is necessary to prevent vapor produced as a byproduct of the chemical reaction, for example water vapor, from condensing on the wafer top surface 53.

Next, the igniter power supply 82 energizes the igniter 78 and the first gas line 56 and second gas line 58 are opened to allow a flow of hydrogen and nitrogen trifluoride gases into the nozzle assembly 48 and through the eight nozzles 51. A combustion flame of H₂ and NF₃ (not shown) ignites. Each nozzle of the eight nozzles 51 in the nozzle assembly 48 requires a flow of 400 sccm resulting in total system flow of 3,200 sccm during processing.

As the wafer 50 rotates either the wafer chuck 46 translates (in a preferred embodiment) or the actuation mechanism 49 moves (in another embodiment) the nozzle assembly 48 and the combustion flame across the wafer top surface 53. As a result a desired section of the wafer top surface 53 is processed. Processing includes the removal of a thin film, for example, silicon dioxide or tantalum as described above in relation to the substrate processing method.

After the wafer is processed, the first gas controller 60 and second gas controller 62 are closed. Simultaneously, the fourth gas controller 77 is opened to allow a flow of argon gas into the nozzle assembly 48 and through the eight nozzles 51 to “blow out” the combustion flame. This step is important to prevent flashback.

The wafer 50 may be removed after the chamber is evacuated of process gases and byproducts. Thus, the wafer top surface 53 is processed to remove a thin film and/or contaminant. This process can be applied to the wafer top surface 53 or to a back side surface. Back side surface processing is often used to remove undesirable thin film deposits formed during prior process steps. One example is back side silicon nitride removal.

The heater 84 provides heating of the wafer top surface 53 to prevent redeposition of reactant byproducts that may condense on the surface. Condensation can be prevented by heating the wafer top surface 53 to a temperature at or above the boiling point for the reactant byproducts, for example heating the wafer top surface 53 above 100° C. to prevent the condensation of water. Alternatively, wafer 50 surface heating can be supplied via a heated substrate holder 44 or via infrared energy directed at the wafer perimeter, or via other heat sources.

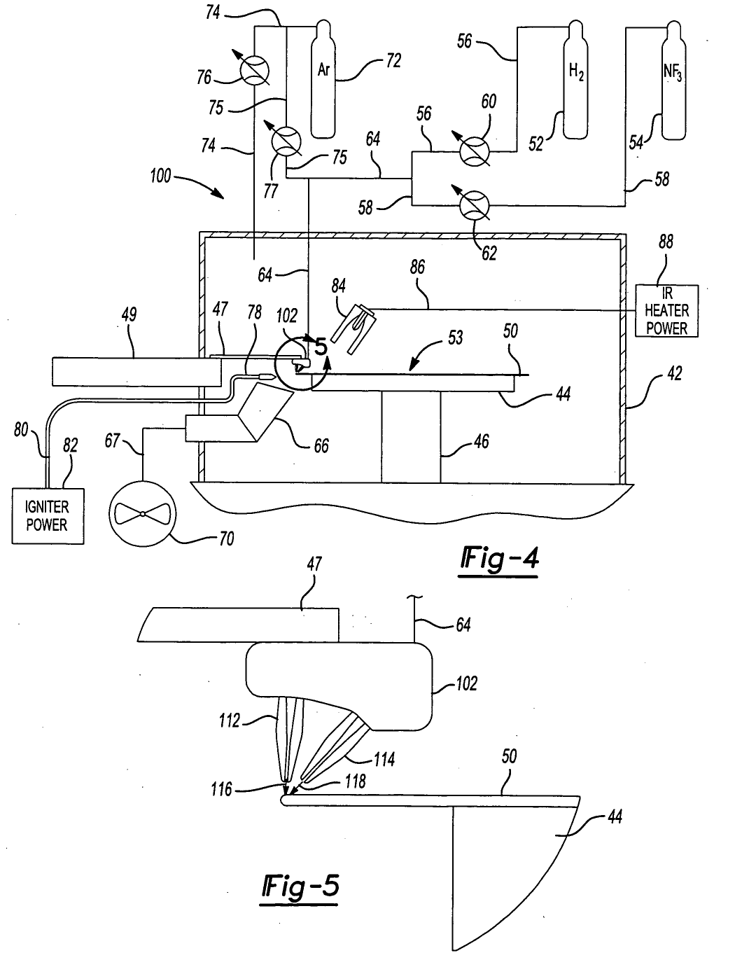

Referring to FIGS. 4 and 5, a substrate edge processing apparatus 100 for use with the above-described substrate processing method includes an edge-type nozzle assembly 102 attached to the support member 47 and held proximate to an edge of the wafer 50. Other components of the substrate edge processing apparatus 100 are the same as for the substrate processing apparatus 40 described above.

The edge-type nozzle assembly 102 has a first nozzle 112 and a second nozzle 114. First nozzle 112 is for directing a laminar flow of reactive species in a first direction 116 towards a top bevel and crown of the edge of the wafer 50. The second nozzle 114 is for directing a laminar flow of the reactive species in a second direction 118 towards the near-edge of the wafer 50. Preferably, first nozzle 112 and second nozzle 114 use an internal diameter of 0.254 mm with an aspect ratio approaching 10:1, length to diameter ratio. This is recommended to develop a laminar flow in the nozzle and produces a more stable combustion discharge. The first nozzle 112 and second nozzle 114 are constructed of sapphire and inserted into the edge-type nozzle assembly 102 as described above in relation to the nozzle assembly 48 and eight nozzles 51. The first nozzle 112 is at an angle of 80° to the wafer top surface 53. The second nozzle 114 is at an angle of 45° to the wafer top surface 53.

Operation of the edge processing apparatus 100 is similar to operation of the substrate processing apparatus 40 described above. In operation, the wafer 50 is first centered on the substrate holder 44 of the substrate chuck 46 in preparation for processing the edge of the wafer 50. The substrate chuck 46 is commanded to rotate at 2 rpm the substrate holder 44 with the wafer 50. Next, the exhaust scoop 66 is activated by energizing the blower device 70. Third gas controller 76 is opened to allow for a flow of argon gas from the argon gas source 72 into the processing chamber 42. Argon gas is allowed to flow into the chamber to substantially create an inert environment within the processing chamber 42. In an embodiment the argon gas may be directed to the process area and the processing chamber 42 may contain other ambient gasses. The processing chamber 42 remains substantially at or near atmospheric pressure.

Heater 84 is energized to heat the wafer top surface 53 proximate to the edge area to be processed. This step is necessary to prevent vapor produced as a byproduct of the chemical reaction from condensing on the wafer top surface 53 and edge area. Next, the ignition power supply 82 energizes the igniter 78 and the first gas line 56 and second gas line 58 are opened to allow a flow of H₂ and NF₃ gases into the edge-type nozzle assembly 102 and through the first nozzle 112 and second nozzle 114. A combustion flame of H₂ and NF₃ (not shown) ignites. The resulting flame impinges upon the near-edge, bevel and crown regions of the wafer 50 thus processing the wafer 50.

As the wafer 50 rotates the combustion flame impinges on the edge area of the wafer 50. As a result the edge area of the wafer 50 is processed. Processing includes the removal of a thin film, for example, silicon dioxide or tantalum as described above in relation to the substrate processing method.

After the wafer is processed, the first gas controller 60 and second gas controller 62 are closed. Simultaneously, the fourth gas controller 77 is opened to allow a flow of argon gas into the edge-type nozzle assembly 102 and through the first nozzle 112 and second nozzle 114 to “blow out” the combustion flame. The wafer 50 may be removed after the chamber is evacuated of process gases and byproducts. Thus, the edge area of the wafer 50 is processed to remove a thin film and/or contaminant.

Although NF₃ is used in the above embodiments as the non-oxygen oxidizer other non-oxygen oxidizers as previously discussed are suitable for use in the preferred embodiments. Further, additional embodiments for isolating and processing a wafer according to the above-described method are disclosed in U.S. Patent Application Ser. No. ______, filed on Sep. 19, 2005 and titled “Method and Apparatus for Isolative Substrate Edge Area Processing.” The disclosure of this application is incorporated herein by reference.

Removal of dielectric thin films such as silicon oxide from substrates using H₂ and NF₃ gas mixtures is performed with a hydrogen fraction in the range of 0.6 to 0.7. For example, if the total flow is 800 sccm, H₂ flow will be in the range of 480 sccm to 560 sccm with NF₃ flow in the range of 320 sccm to 240 sccm. IR preheat is used in cases where ambient oxygen is present to discourage combustion products from condensing on the substrate.

Removal of tantalum from the near-edge region of the substrate is carried out using an etch nozzle configuration similar to that detailed for dielectric removal. Total gas flows are approximately 800 sccm with an H₂ fraction in the range of 0.6 to 0.7. The primary tantalum etch product is TaF₅ which has a boiling point of ˜230° C. Substrate surface temperatures in the etch region must be kept about this temperature to prevent condensation of the etch product. This is readily achieved using an additional combustion flame nozzle (not shown) positioned to impinge a flame on the substrate immediately prior to the impingement of the etch flame. This pre-heat nozzle discharges a flame of H₂ and O₂ preferably in the range of 0.5 to 0.8, H₂ fraction at a total flow of ˜400 sccm for a single nozzle.

Etching of the edge area of the wafer 50 proceeds at an expedited rate by using the described substrate edge processing apparatus 100 with the substrate processing method 10 (FIGS. 1A-1C). A rate of etching of the edge portion of the wafer 50 can be calculated based on consideration of exposure width, wafer circumference and rotational speed. For example, consider a 200 mm circumferential wafer with 2,000 Å of SiO₂ that is rotated at 2 rpm and the SiO₂ thin film on the edge area is completely removed in one rotation. Assuming a conservative exposure width of 5 mm of the combustion flame effluent on the wafer edge (using a 0.256 mm nozzle bore) an exposure fraction can be calculated as 5 mm/(628 mm×2 rev/min)=0.004 min/rev. The etch rate can then be approximated by dividing the 2,000 Å/rev removal by the exposure fraction. That is 2,000 Å/rev/0.004 min/rev=500,000 Å/min SiO₂ removal. If a smaller 2 mm exposure width is assumed then the removal rate becomes 1,256,000 Å/min. Based on these considerations and assumptions a poly-silicon thin film would be etched at an approximate rate of 3×10⁶ Å/min; a photoresist thin film would be etched at an approximate rate of 4.6×10⁶ Å/min; and a tantalum thin film would be etched at an approximate rate of 1×10⁶ Å/min. This is a significantly high rate of etching resulting in a high rate of processing throughput of wafers.

Thus, a relatively efficient and cost effective method and apparatus is provided that will not result in damage to the substrate or the necessity of performing further processing steps. The described substrate processing method and apparatus avoids the inherent problems with wet chemical, dry plasma, and abrasive methods of processing a wafer including the processing of the edge area. Advantages include, but are not limited to: speed of process and related process throughput; processing at substantially an atmospheric pressure; not causing ionic damage; and providing the ability to precisely treat discreet areas of the substrate surface. A further benefit related to processing the edge of the wafer is a smooth etch transition profile from full thickness to reduced or zero thickness. These are important advantages in substrate wafer processing.

The description of the embodiments is merely exemplary in nature and, thus, variations that do not depart from the gist of the invention are intended to be within the scope of the invention. Such variations are not to be regarded as a departure from the spirit and scope of the invention.

What is claimed is:

1. A substrate surface etching method, comprising:
igniting a combustion flame comprising hydrogen and a non-oxygen oxidizer gas; and
directing the combustion flame onto the substrate surface.

2. The substrate surface etching method of claim 1 further comprising flowing an inert gas over at least a portion of the substrate surface.

3. The method of claim 2 wherein the inert gas is argon.

4. The substrate surface etching method of claim 1 wherein the method is performed at a substantially atmospheric pressure.

5. The substrate surface etching method of claim 1 wherein the substrate surface is preheated using a fiber coupled laser diode array before directing the combustion flame onto the substrate surface.

6. The substrate surface etching method of claim 1 wherein the substrate surface is preheated proximally to where the combustion flame will be directed.

7. The substrate surface etching method of claim 1 wherein the method is performed in a substantially non-ionized environment.

8. The substrate surface etching method of claim 1 wherein the non-oxygen oxidizer is nitrogen trifluoride.

9. The method of claim 8 wherein the molar ratio of said hydrogen to said nitrogen trifluoride is substantially 3:2.

10. The substrate surface etching method of claim 1 wherein the combustion flame is directed towards an edge portion of the substrate surface.

11. The method of claim 10 wherein the substrate is rotated wherein the edge area of the substrate surface is etched.

12. The substrate surface etching method of claim 1 wherein a material etched is SiO₂.

13. The substrate surface etching method of claim 1 wherein a material etched is Si.

14. The substrate surface etching method of claim 1 wherein a material etched is Ta.

15. The substrate surface etching method of claim 1 wherein the non-oxygen oxidizer is fluorine (F₂).

16. The substrate surface etching method of claim 1 wherein the non-oxygen oxidizer is chlorine (Cl₂).

17. The substrate surface etching method of claim 1 wherein the non-oxygen oxidizer is chlorine trifluoride (ClF₃).

18. A substrate wafer processed according to the method of claim 1.

19. A method of removing at least a portion of a material from a surface of a substrate, the method comprising:
exposing the surface of the substrate to a substantially non-ionized combustion flame of hydrogen and nitrogen trifluoride gas.

20. The method of claim 19 wherein the exposing of the surface of the substrate is also in the presence of an inert gas.

21. The method of claim 19 wherein the exposing of the surface of the substrate is substantially at atmospheric pressure.

22. The method of claim 19 further comprising heating the substrate before the exposing of the surface of the substrate.

23. The method of claim 19 further comprising directing the combustion flame towards the edge of the substrate.

24. The method of claim 19 further comprising directing the combustion flame in a radial outward direction from the center of the substrate towards an edge of the substrate.

25. A substrate wafer etched according to the method of claim 19.

26. A substrate processing method comprising:
providing an inert environment;
igniting a combusting flame of hydrogen and a non-oxygen oxidizer in the inert environment; and
directing the combustion flame onto a substrate.

27. A substrate processing apparatus for processing the substrate with a combustion flame of hydrogen and a non-oxygen oxidizer, comprising:
a processing chamber for receiving the substrate and for confining an inert environment for the combustion flame of hydrogen and the non-oxygen oxidizer wherein the processing chamber maintains a substantially atmospheric pressure;
a source for hydrogen and the non-oxygen oxidizer operationally attached to the processing chamber; and
a nozzle assembly within the processing chamber for directing the combustion flame onto the substrate.

28. The substrate processing apparatus for processing the substrate with a combustion flame of hydrogen and a non-oxygen oxidizer of claim 27, wherein the nozzle assembly comprises two or more nozzles.

29. The substrate processing apparatus of claim 28 wherein the two or more nozzles are made of sapphire.

30. The substrate processing apparatus of claim 28 wherein the two or more nozzles are made of a material selected from the group consisting of yttria (Y₂O₃), magnesium fluoride (MgF₂) and magnesium oxide (MgO).

31. The substrate processing apparatus for processing the substrate with a combustion flame of hydrogen and a non-oxygen oxidizer of claim 27, wherein the nozzle assembly comprises two or more nozzles wherein the two or more nozzles are retained at an angle from a top surface of a substrate to be processed.

32. A substrate processing apparatus comprising:
a processing chamber maintained substantially at an atmospheric pressure; and
a nozzle assembly having a plurality of nozzles for directing a flow of a reactive species wherein the nozzles are made of a material selected from the group consisting of sapphire, yttria (Y₂O₃), magnesium fluoride (MgF₂) and magnesium oxide (MgO).

33. The substrate processing apparatus of claim 32 wherein the nozzles have a length to diameter ratio substantially 10:1.
